(19) United States
(12) Patent Application Publication
(10) Pub. No.: US 2022/0007518 A1
(43) Pub. Date: Jan. 6, 2022

(54) USING SOLDER STANDOFFS DURING REFLOW TO REDUCE VOIDING WITH CIRCUIT BOARDS

(71) Applicant: Loon LLC, Mountain View, CA (US)

(72) Inventors: Keith Fries, San Jose, CA (US); Vineethkumar Nair, San Jose, CA (US)

(21) Appl. No.: 16/917,955

(22) Filed: Jul. 1, 2020

(51) Int. Cl. H05K 3/34; H05K 1/18; B23K 1/008

(52) U.S. Cl. CPC H05K 3/341; H05K 3/3494; B23K 2101/42; B23K 1/008; H05K 2201/10053; H05K 1/181

(57) ABSTRACT

Aspects of the technology employ significantly reduce void formation beneath critical components on a printed circuit board (PCB). This is accomplished using advanced fabrication techniques that include employing alignment fixtures and solder standoffs to position duplexers, using nitrogen gas during the reflow process, and maintaining specific temperature and “time above liquideous” (TAL) controls. Certain types of components, such as duplexers used in communication circuit boards, can be highly susceptible to voids. Because such components are relatively large and block x-rays, it is challenging to determine whether voids have been formed beneath them. Thus, in many instances conventional fabrication techniques are insufficient to produce viable circuit boards that minimize void formation within acceptable tolerances. It may be mission critical to minimize voids, such as for PCBs used in communication modules deployed on high altitude platforms intended to operate in the stratosphere for extended periods of time.

### BACKGROUND

Fabrication of electronic circuits, such as components assembled on a printed circuit board (PCB), typically includes soldering of components onto the PCB or other substrate. Unfortunately, defects in the fabrication process can adversely impact component operation or render an entire electronics module inoperable, for instance due to poor electrical or thermal conductivity, or insufficient mechanical connectivity. One type of defect is a void, in particular a hole or region within a solder joint in which the solder is substantially or entirely missing. The formation of voids may occur due to different reasons, such as outgassing of flux in solder paste, vias in pads, or solder paste quality impacting its rheological properties.

Certain procedures, such as reflow or adding more solder, can be employed to reduce voiding. However, these procedures may be ineffective on their own when manufacturing circuitry that includes large or heavy components, especially components with strict alignment requirements. For example, duplexers that are employed in communication circuitry may be very susceptible to voiding. It may also be difficult to detect voids beneath duplexers and other large components that may partially or completely block x-rays. Conventional manufacturing techniques can be insufficient when fabricating a communication module having duplexers or similar components. This issue can be compounded when the communication module is intended for use in extreme environments, such as the stratosphere, where very low temperatures and/or large swings in environmental conditions can accelerate system failures. These failures may be catastrophic, particularly when there is no feasible way to repair or replace the communication module when it is in the extreme environment.

### SUMMARY

Telecommunications connectivity via the Internet, cellular data networks and other systems is available in many parts of the world. However, there are many locations where such connectivity is unavailable, unreliable or subject to outages from natural disasters. Some systems may provide network access to remote locations or to locations with limited networking infrastructure via satellites or high altitude platforms (HAPs) located in the stratosphere. In the latter case, the communication equipment providing, e.g., LTE and/or 5G services, may be expected to operate for weeks, months or longer in a harsh environment without the possibility for repair should the equipment fail. Void-based failures associated with duplexers and other components thus can adversely impact the ability of the platform to provide communication connectivity, which may necessitate launching of additional HAPs in a fleet in order to address a communication coverage deficiency.

Aspects of the technology employ advanced circuit board fabrication techniques that include using alignment fixtures and solder standoffs to position dielectric filter components such as duplexers, using nitrogen gas during the reflow process, and maintaining specific temperature and “time above liquideous” (TAL) controls to ensure the temperature difference between the duplexers and other PCB elements fall within acceptable tolerance limits.

According to one aspect, a method of fabricating a printed circuit board is provided. The method comprises printing solder paste onto a plurality of contact areas of the printed circuit board; placing a set of solder preforms onto a subset of the plurality of contact areas having the printed solder paste, wherein an amount of solder paste for each of the solder preforms is selected based on a pad size of each of the subset of contact areas; placing a first set of components on the printed circuit board after printing the solder paste; placing one or more alignment fixtures on the printed circuit board; placing a second set of components on the printed circuit board, wherein the one or more alignment fixtures are placed so that the second set of components remains in place during fabrication of the printed circuit board; after the one or more alignment fixtures and the second set of components are placed, performing a reflow process to heat the solder paste and the set of solder preforms to a first temperature according to a selected temperature profile; and upon ending the reflow process and reaching a second temperature below the first temperature, removing the one or more alignment fixtures.

In one example, the set of solder preforms placed on the subset of the plurality of contact areas are arranged so that the subset of contact areas are corner pads for the second set of components. In another example, each one of the solder preforms of the set comprises a pair of standoffs placed on the printed solder paste. In this case, the amount of solder paste for each of the solder preforms may be on the order of 2 kmil³ to 15 kmil³ in volume. In one scenario, the pad size may be either a 0201 size or a 0402 size. In an example, placing the first set of components occurs in conjunction with placing the set of solder preforms.

Performing the reflow process according to the selected temperature profile may include maintaining the first temperature for a selected time above liquideous. The time at above liquideous may be between 30 and 100 seconds. Achieving the first temperature may include ramping up the temperature at a selected rate. Here, the selected rate may be no more than 1° C.-3° C. per second.

In an example, the method further comprises performing the reflow process in the presence of nitrogen gas. In another example, the selected temperature profile and selected time above liquideous are chosen so that a temperature difference between the second set of components and one or more of the first set of components is maintained within a determined tolerance limit. Here, the second set of components may comprise a pair of duplexers. In this case, the one or more of the first set of components comprises a mechanical relay disposed between the pair of duplexers.

In a further example, the second temperature is room temperature. And in yet another example, the method also includes, after removing the one or more alignment fixtures, performing one or more of testing circuitry of the fabricated printed circuit board, inspecting at least some solder joints formed by the reflow process, and analyzing voids along the printed circuit board to determine whether such voids meet one or more predetermined criteria.

According to another aspect, a printed circuit board is fabricated by the method described above. Here, for instance the second set of components may comprise a pair of duplexers, and one or more of the first set of components may comprise a mechanical relay disposed between the pair of duplexers. In an example, a total size by surface area of all voids along the printed circuit board do not exceed 25%, and any individual void does not exceed 10% of the total size.

According to a further aspect, a communication system comprises one or more printed circuit boards fabricated by the method described above. In an example, the communication system may include a high altitude platform configured to operate in the stratosphere.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a functional diagram of an example system in accordance with aspects of the technology.

FIG. 2 illustrates a balloon configuration in accordance with aspects of the technology.

FIG. 3 is an example payload arrangement in accordance with aspects of the technology.

FIG. 4 is an example x-ray image of a printed circuit board in accordance with aspects of the technology.

FIG. 5 illustrates an example of void formation beneath an electronic component of a printed circuit board.

FIGS. 6 A-B illustrates before and after placement of an electronic component on a printed circuit board in accordance with aspects of the technology.

FIG. 7 illustrates an example PBC with alignment fixtures in accordance with aspects of the technology.

FIG. 8 illustrates an angled x-ray of a PCB showing voids along different areas of the PCB.

FIGS. 9-C illustrates examples of solder and standoffs in accordance with aspects of the technology.

FIGS. 10A-B illustrate example x-ray images of PCB sections showing void reduction in accordance with aspects of the technology.

FIGS. 11A-B illustrate microsectioned PCBs with and without void reduction in accordance with aspects of the technology.

FIG. 12 illustrates a method in accordance with aspects of the technology.

### DETAILED DESCRIPTION

### Overview

The technology relates to processes for reducing voids during PCB fabrication, such as for communication devices that include duplexers and other relatively large components. Reduction of voids to below a threshold level may be mission critical for systems such as communication modules deployed on HAPs intended to operate in the stratosphere for extended periods of time. Electrical, thermal and/or mechanical failures of such components due to voids may render the entire communication system of a HAP inoperable or severely degraded.

Stratospheric HAPs, such as balloon-based HAPs, may have a float altitude of between about 50,000-120,000 feet above sea level. At such heights, the density of the air is very low compared to ground level. For example, while the pressure at ground level is around 1,000 mbar, the pressure in the lower stratosphere may be on the order of 100 mbar and the pressure in the upper stratosphere may be on the order of 1 mbar. The temperature in the stratosphere generally increases with altitude. For instance, in the lower stratosphere the average temperature may be on the order of −40° C. to −100° C. or colder, while the average temperature in the upper stratosphere may be on the order of −15° C. to −5° C. or warmer. In addition, while balloons and other HAPs in the stratosphere generally fly above the clouds and most weather conditions, the HAPs can be impacted by lightning-induced transients beneath them. Such environmental conditions can cause component or system-wide failures, which can reduce or cut short the HAP's operational lifetime. This may be especially true with voids impacting electronic circuitry.

The systems and processes discussed below are configured to minimize the impact of voids on such circuitry. While these solutions are beneficial for PCB fabrication in general, including communication circuitry, they are particular helpful for communication modules operating in extreme environments such as the stratosphere.

### Example Stratospheric Hap Systems

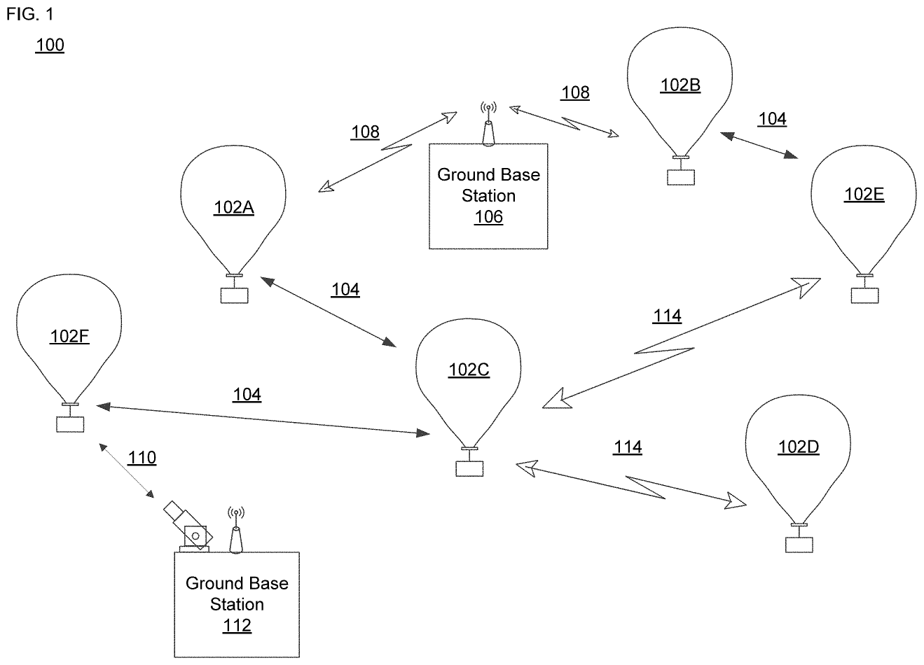

FIG. 1 depicts an example system 100 in which a fleet of balloons, airships or other HAPs described above may be used. This example should not be considered as limiting the scope of the disclosure or usefulness of the features described herein. System 100 may be considered a HAP network. In this example, network 100 includes a plurality of devices, such as balloons or other lighter-than-air craft 102A-F as well as ground base stations 106 and 112. The network 100 may also include a plurality of additional devices, such as various computing devices (not shown) as discussed in more detail below or other systems that may participate in the network.

The devices in system 100 are configured to communicate with one another. As an example, the HAPs may include communication links 104 and/or 114 in order to facilitate intra-balloon communications. By way of example, links 114 may employ radio frequency (RF) signals (e.g., millimeter wave transmissions) while links 104 employ free-space optical transmission. Alternatively, all links may be RF, optical, or a hybrid that employs both RF and optical transmission. In this way balloons 102A-F may collectively function as a mesh network for data communications. At least some of the HAPs may be configured for communications with ground-based stations 106 and 112 via respective links 108 and 110, which may be RF and/or optical links.

In one scenario, a given balloon-type HAP 102 may be configured to transmit an optical signal via an optical link 104. Here, the given balloon 102 may use one or more high-power light-emitting diodes (LEDs) to transmit an optical signal. Alternatively, some or all of the balloons 102 may include laser systems for free-space optical communications over the optical links 104. Other types of free-space communication are possible. Further, in order to receive an optical signal from another balloon via an optical link 104, the balloon may include one or more optical receivers.

The HAPs may also utilize one or more of various RF air-interface protocols for communication with ground-based stations via respective communication links. For instance, some or all of balloons 102A-F may be configured to communicate with ground-based stations 106 and 112 via RF links 108 using various protocols described in IEEE 802.11 (including any of the IEEE 802.11 revisions), cellular protocols such as GSM, CDMA, UMTS, EV-DO, WiMAX, and/or LTE, 5G and/or one or more proprietary protocols developed for long distance communication, among other possibilities. The ground-based stations may include client devices such as mobile phones, computers, etc.

In some examples, the links may not provide a desired link capacity for HAP-to-ground communications. For instance, increased capacity may be desirable to provide backhaul links from a ground-based gateway. Accordingly, an example network may also include downlink balloons, which could provide a high-capacity air-ground link between the various HAPs of the network and the ground base stations. For example, in network 100, balloon 102F may be configured as a downlink balloon that directly communicates with station 112.

Like other HAPs in network 100, downlink balloon 102F may be operable for communication (e.g., RF or optical) with one or more other balloons via link(s) 104. Downlink balloon 102F may also be configured for free-space optical communication with ground-based station 112 via an optical link 110. Optical link 110 may therefore serve as a high-capacity link (as compared to an RF link 108) between the network 100 and the ground-based station 112. Downlink balloon 102F may additionally be operable for RF communication with ground-based stations 106. In other cases, downlink balloon 102F may only use an optical link for balloon-to-ground communications. Further, while the arrangement shown in FIG. 1 includes just one downlink balloon 102F, an example balloon network can also include multiple downlink balloons. On the other hand, a balloon network can also be implemented without any downlink balloons.

A downlink HAP may be equipped with a specialized, high bandwidth RF communication system for balloon-to-ground communications, instead of, or in addition to, a free-space optical communication system. The high bandwidth RF communication system may take the form of an ultra-wideband system, which may provide an RF link with substantially the same capacity as one of the optical links 104.

In a further example, some or all of HAPs 102A-F could be configured to establish a communication link with space-based satellites and/or other types of HAPs (e.g., drones, airplanes, airships, etc.) in addition to, or as an alternative to, a ground based communication link. In some embodiments, a balloon may communicate with a satellite or another high altitude platform via an optical or RF link. However, other types of communication arrangements are possible.

Each of the communication approaches noted above may employ one or more communication modules. As discussed further below, these modules may include duplexers, multiplexers and other components that may be significantly affected by voids created during the circuit board fabrication process.

The balloons of FIG. 1 may be high-altitude balloons that are deployed in the stratosphere. As an example, in a high altitude balloon network, the balloons may generally be configured to operate at stratospheric altitudes, e.g., between 50,000 ft and 70,000 ft or more or less, in order to limit the balloons' exposure to high winds and interference with commercial airplane flights. In order for the balloons to provide reliable communication in the stratosphere, where winds may affect the locations of the various balloons in an asymmetrical manner, the balloons may be configured to move latitudinally and/or longitudinally relative to one another by adjusting their respective altitudes, such that the wind carries the respective balloons to the respectively desired locations. And as discussed below, lateral propulsion may also be employed to affect the balloon's path of travel.

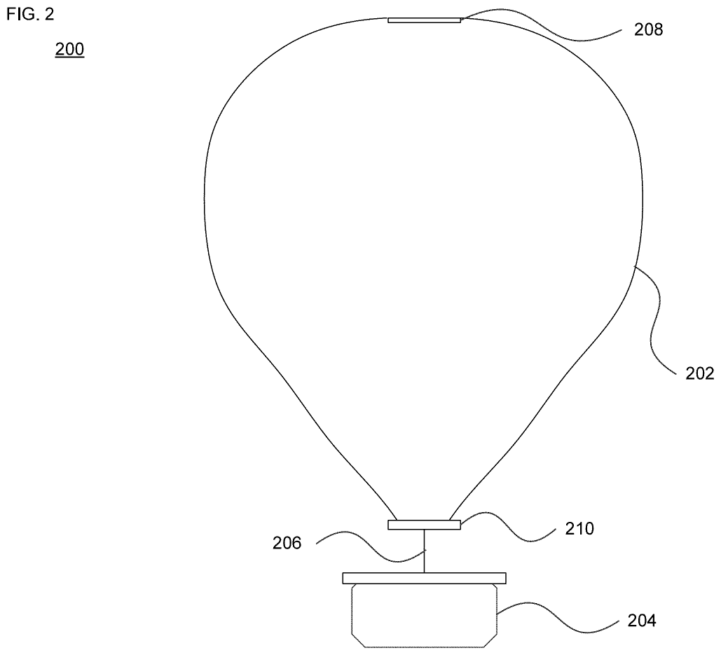

In an example configuration, a balloon-type HAP includes an envelope and a payload, along with various other components. FIG. 2 is one example of a high-altitude balloon 200, which may represent any of the balloon HAPs of FIG. 1. As shown, the example balloon 200 includes an envelope 202, a payload 204 and a coupling member (e.g., a down connect) 206 therebetween. At least one gore panel forms the envelope, which is configured to maintain pressurized lifting gas therein. For instance, the balloon may be a superpressure balloon. A top plate 208 may be disposed along an upper section of the envelope, while a base plate 210 may be disposed along a lower section of the envelope opposite the top place. In this example, the coupling member 206 connects the payload 204 with the base plate 210.

The envelope 202 may take various shapes and forms. For instance, the envelope 202 may be made of materials such as polyethylene, mylar, FEP, rubber, latex or other thin film materials or composite laminates of those materials with fiber reinforcements imbedded inside or outside. Other materials or combinations thereof or laminations may also be employed to deliver required strength, gas barrier, RF and thermal properties. Furthermore, the shape and size of the envelope 202 may vary depending upon the particular implementation. Additionally, the envelope 202 may be filled with different types of gases, such as air, helium and/or hydrogen. Other types of gases, and combinations thereof, are possible as well. Shapes may include typical balloon shapes like spheres and “pumpkins”, or aerodynamic shapes that are symmetric, provide shaped lift, or are changeable in shape. Lift may come from lift gasses (e.g., helium, hydrogen), electrostatic charging of conductive surfaces, aerodynamic lift (wing shapes), air moving devices (propellers, flapping wings, electrostatic propulsion, etc.) or any hybrid combination of lifting techniques.

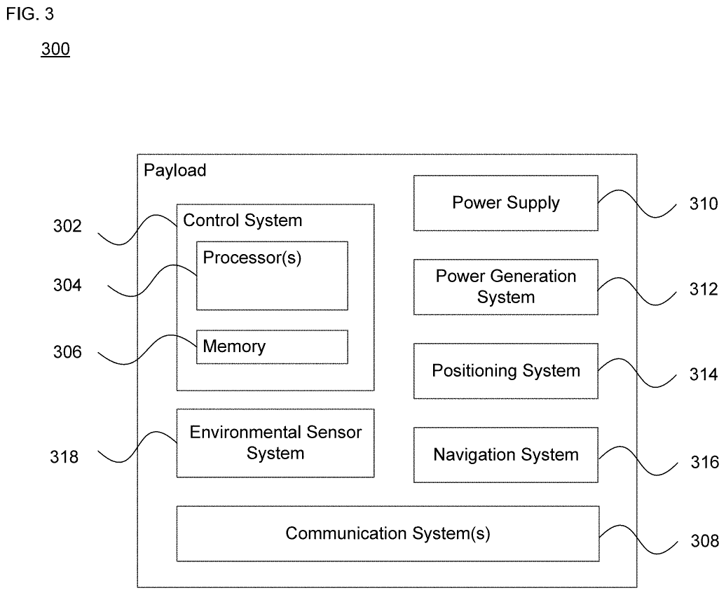

According to one example shown in FIG. 3, a payload 300 of a balloon or other HAP platform includes a control system 302 having one or more processors 304 and on-board data storage in the form of memory 306. Memory 306 stores information accessible by the processor(s) 304, including instructions that can be executed by the processors. The memory 306 also includes data that can be retrieved, manipulated or stored by the processor. The memory can be of any non-transitory type capable of storing information accessible by the processor, such as a hard-drive, memory card (e.g., thumb drive or SD card), ROM, RAM, and other types of write-capable, and read-only memories. The instructions can be any set of instructions to be executed directly, such as machine code, or indirectly, such as scripts, by the processor. In that regard, the terms “instructions,” “application,” “steps” and “programs” can be used interchangeably herein. The instructions can be stored in object code format for direct processing by the processor, or in any other computing device language including scripts or collections of independent source code modules that are interpreted on demand or compiled in advance. The data can be retrieved, stored or modified by the one or more processors 304 in accordance with the instructions.

The one or more processors 304 can include any conventional processors, such as a commercially available CPU. Alternatively, each processor can be a dedicated component such as an ASIC, controller, or other hardware-based processor. Although FIG. 3 functionally illustrates the processor(s) 304, memory 306, and other elements of control system 302 as being within the same block, the system can actually comprise multiple processors, computers, computing devices, and/or memories that may or may not be stored within the same physical housing. For example, the memory can be a hard drive or other storage media located in a housing different from that of control system 302. Accordingly, references to a processor, computer, computing device, or memory will be understood to include references to a collection of processors, computers, computing devices, or memories that may or may not operate in parallel.

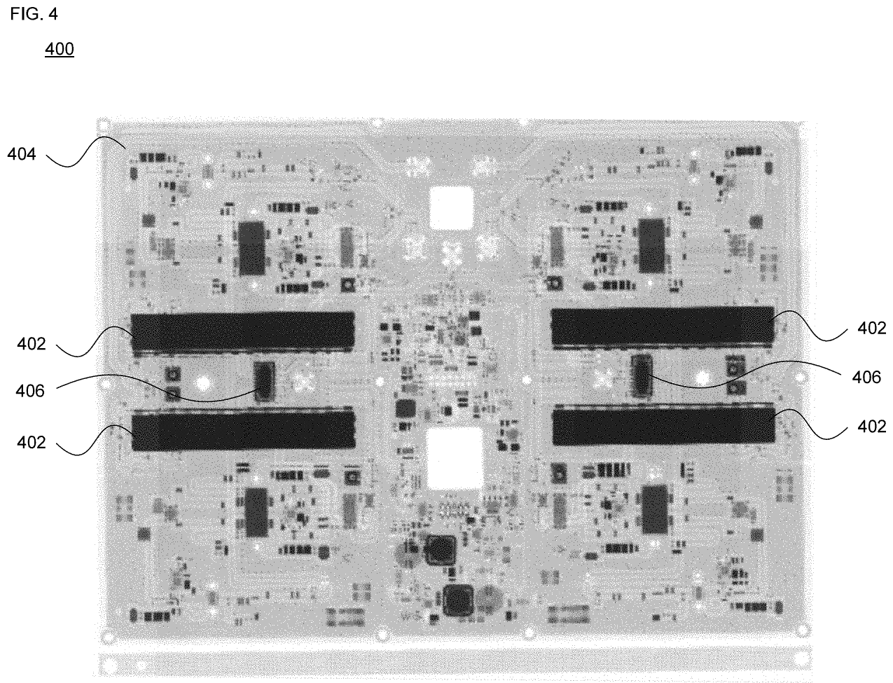

The payload 300 may also include various other types of equipment and systems to provide a number of different functions. For example, as shown the payload 300 includes one or more communication systems 308, which may transmit signals via RF and/or optical links as discussed above. The communication system(s) 308 include communication components such as one or more transmitters and receivers (or transceivers), one or more antennae, and a baseband processing subsystem (not shown). One or more duplexers (see FIG. 4) may be included in the communication system(s) 308.

The payload 300 is illustrated as also including a power supply 310 to supply power to the various components of balloon. The power supply 310 could include one or more rechargeable batteries or other energy storage systems like capacitors or regenerative fuel cells. In addition, the payload 300 may include a power generation system 312 in addition to or as part of the power supply. The power generation system 312 may include solar panels, stored energy (hot air), relative wind power generation, or differential atmospheric charging (not shown), or any combination thereof, and could be used to generate power that charges and/or is distributed by the power supply 310.

The payload 300 may additionally include a positioning system 314. The positioning system 314 could include, for example, a global positioning system (GPS), an inertial navigation system, and/or a star-tracking system. The positioning system 314 may additionally or alternatively include various motion sensors (e.g., accelerometers, magnetometers, gyroscopes, and/or compasses). The positioning system 314 may additionally or alternatively include one or more video and/or still cameras, and/or various sensors for capturing environmental data. Some or all of the components and systems within payload 300 may be implemented in a radiosonde or other probe, which may be operable to measure, e.g., pressure, altitude, geographical position (latitude and longitude), temperature, relative humidity, and/or wind speed and/or wind direction, among other information.

Payload 300 may include a navigation system 316 separate from, or partially or fully incorporated into control system 302. The navigation system 316 may implement station-keeping functions for the HAP to maintain position within and/or move to a position in accordance with a desired communication coverage or other service requirement. In particular, the navigation system 316 may use wind data (e.g., from onboard and/or remote sensors) to determine altitudinal and/or lateral positional adjustments that result in the wind carrying the balloon in a desired direction and/or to a desired location. Lateral positional adjustments may also be handled directly by a lateral positioning system that is separate from the payload. Alternatively, the altitudinal and/or lateral adjustments may be computed by a central control location and transmitted by a ground based, air based, or satellite based system and communicated to the HAP. In other embodiments, specific HAPs may be configured to compute altitudinal and/or lateral adjustments for other HAPs and transmit the adjustment commands to those other HAPs.

An environmental sensor system 318 is also shown, which may encompass some or all of the probes and other sensors mentioned above. In addition, the environmental sensor system 318 includes other sensors configured to detect information associated with lightning and other environmental conditions.

### Example Circuit Board Fabrication Approaches

FIG. 4 illustrates an example 400 of an x-ray image of a printed circuit board (PCB), for instance which may be used in a communication module of a HAP as described above. X-ray images may be taken in order to inspect individual solder joints. As seen in this example, a set of duplexers 402 are arranged on PCB 404. And in between adjacent pairs of duplexers 402 are mechanical relays 406. The duplexers 402 and relays 406 are very dark in the image, indicating that they substantially or completely block x-rays. Thus, unless specialized equipment or particular angles are used, x-raying the PCB 404 will not indicate whether there are voids beneath such components. As a result, failures may only be detectable, in some instances, during RF calibration of the communication module. And by that time, it may be too late to address any defects from the fabrication process.

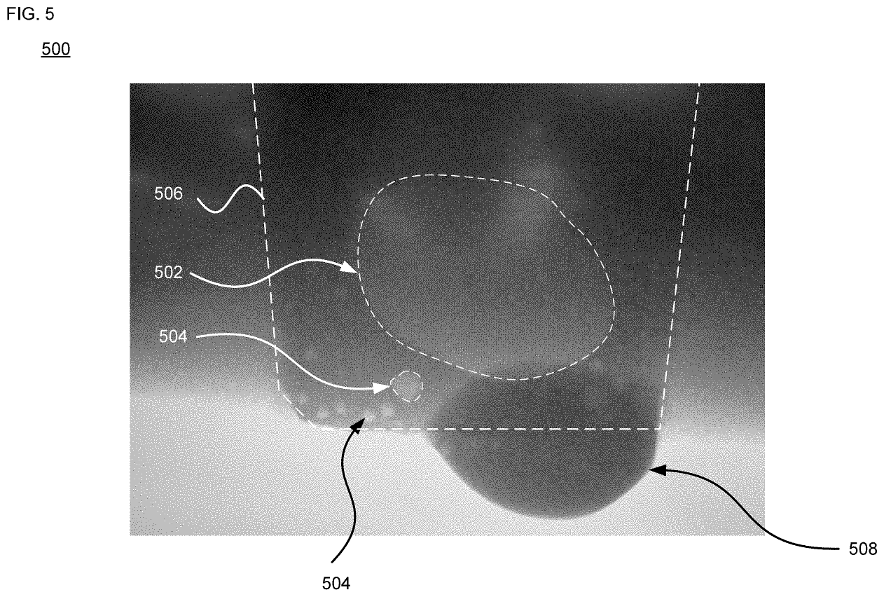

FIG. 5 illustrates an image 500 showing an example of voiding beneath a duplexer, such as any of the duplexers 402 of FIG. 4. Here, a large void 502 can be seen adjacent to a number of smaller voids 504 within a solder region 506 (bounded by dashed lines). Also shown is a solder ball 508 adjacent to the large void 502. In this example, the solder ball 508 was added after the solder region 506 was formed; however, it does not overcome potential issues involving the void 502.

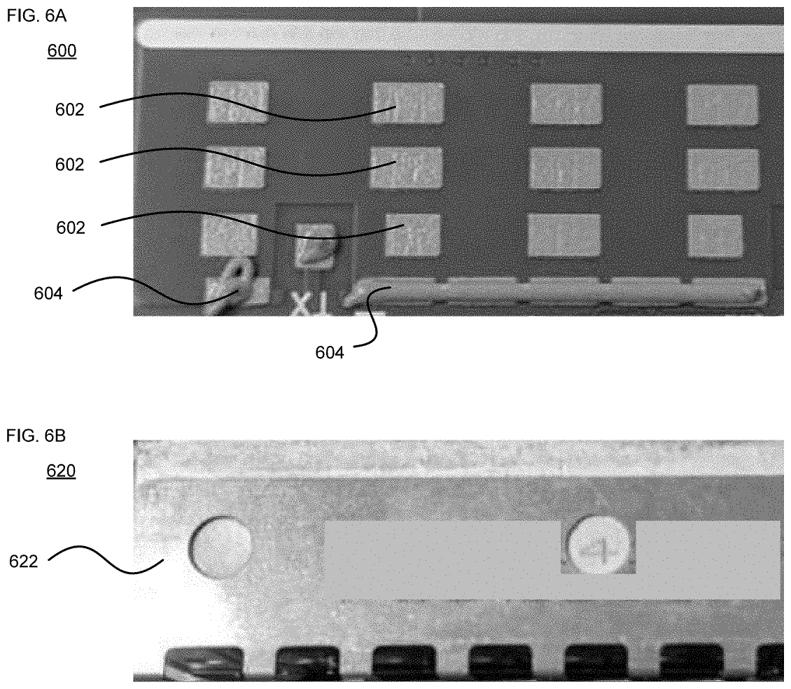

FIGS. 6A-B illustrate photographs of a portion of a PCB before and after a duplexer has been placed on it. As seen in view 600 of FIG. 6A, there are a series of pads 602 disposed along the PCB. These pads have solder already applied. Some pads have additional solder 604, as shown along the bottom left area of the image. The additional solder 604 may be added manually, which makes it difficult to ensure consistency of the amount of solder and repeatability in the specific placement of the additional solder. FIG. 6B illustrates view 620, in which the duplexer 622 has been placed on the pads 602. These pads cannot be readily inspected after the duplexer has been placed on them.

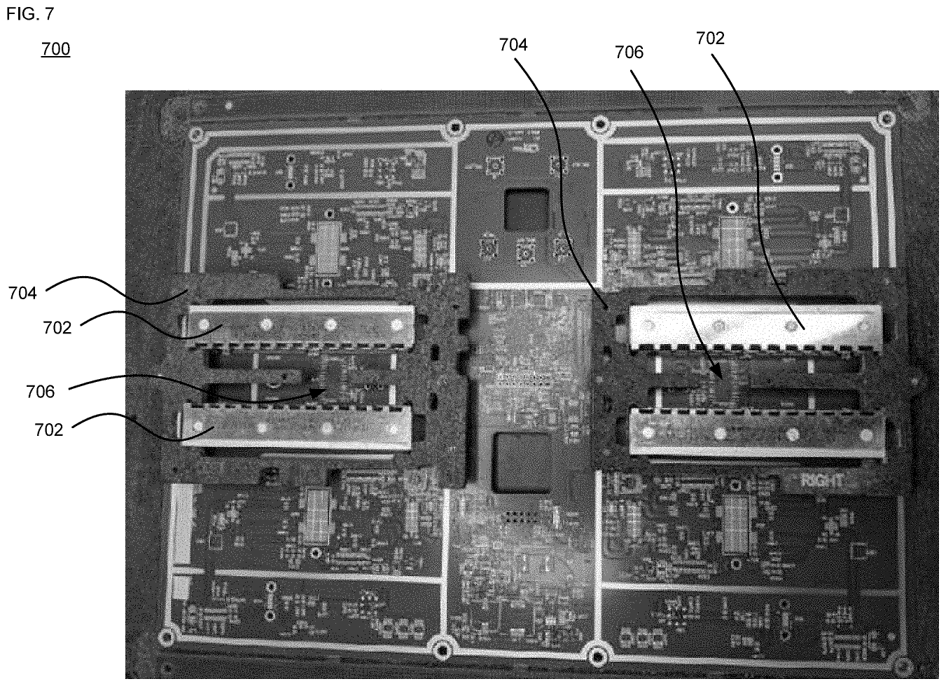

FIG. 7 illustrates a PCB 700 with duplexers 702 arranged over the pads, such as pads 602 of FIG. 6A. As can be seen, the duplexers 702 are large components taking up a substantial portion of the space along the PCB 700. The duplexers 702 can have strict alignment requirements and may be relatively heavy. By way of example, the duplexers 702 may be required to be aligned within +1-0.2 mm of the pad opening. Thus, as shown, alignment fixtures 704 may be required in order to ensure that the duplexers 702 maintain proper alignment. However, the alignment fixtures 704 may restrict airflow and retain heat, which can adversely impact the reflow profile during the fabrication process. The alignment fixtures 704 are removed after completion of the reflow thermal cycle that solders the duplexers to the PCB pads.

As seen by arrows 706, spaces for mechanical relays (not shown) are disposed between pairs of the duplexers 702. Another fabrication challenge is that the mechanical relays may be thermally sensitive. Even though a certain temperature profile may be desired in order to prevent void formation beneath the duplexers, this profile may be too hot for the mechanical relays, which can result in damage to the relays. In addition, manual addition of solder balls along edges of a duplexer (e.g., solder ball 508 in FIG. 5), may also damage the adjacent relay and cause it to fail.

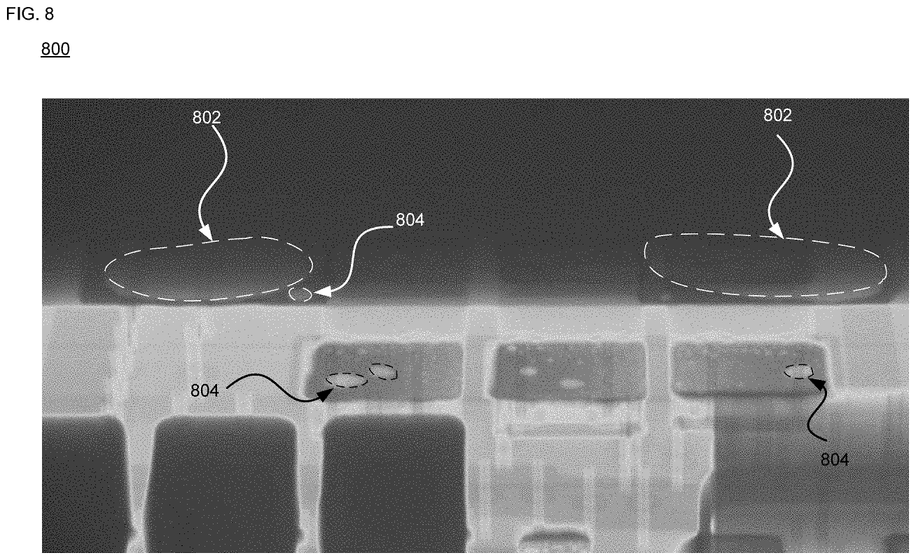

FIG. 8 illustrates an angled x-ray view 800 of a sample PCB with large voids 802 and small voids 804 encircled by dashed lines for clarity. Other voids may be seen under surface mount (SMT) components, such as quad flat no-lead (QFN) packages and ball grid arrays (BGAs). As shown below, by carefully controlling reflow temperature, TAL and other factors, the size of individual voids and the relative percentage of voids to surface area can be reduced significantly.

According to one set of criteria, e.g., IPC-A-610, the total size (by surface area) of all voids should not exceed 25%, while any individual void should not exceed 10% of the total size. In order to satisfy such criteria, one process according to aspects of the technology, the peak solder reflow temperature at the duplexers is limited to no more than 232° C., while the maximum temperature difference (delta) between the duplexers and the mechanical relays is 21° C.

The time above liquideous (TAL) should be carefully controlled as well. In one scenario, the TAL is between 30-100 seconds and the peak temperature range is on the order of 235° C.-245° C.

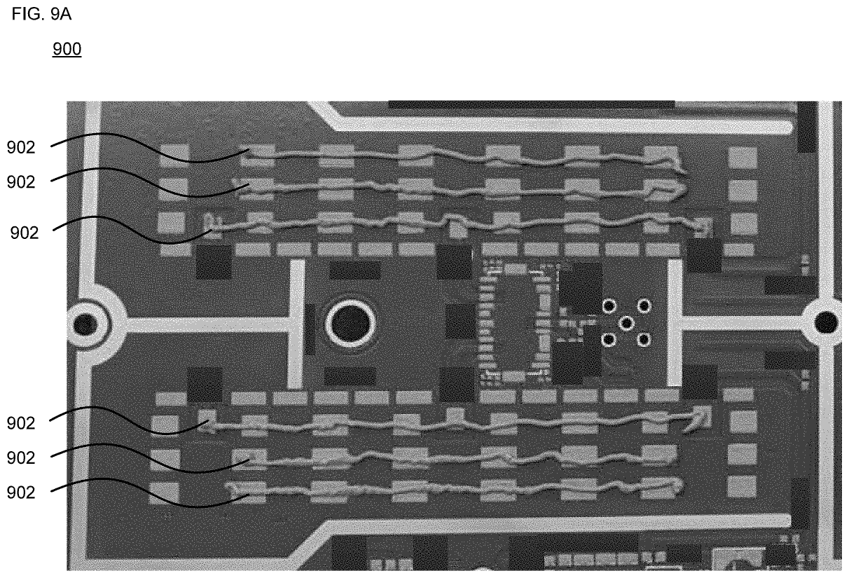

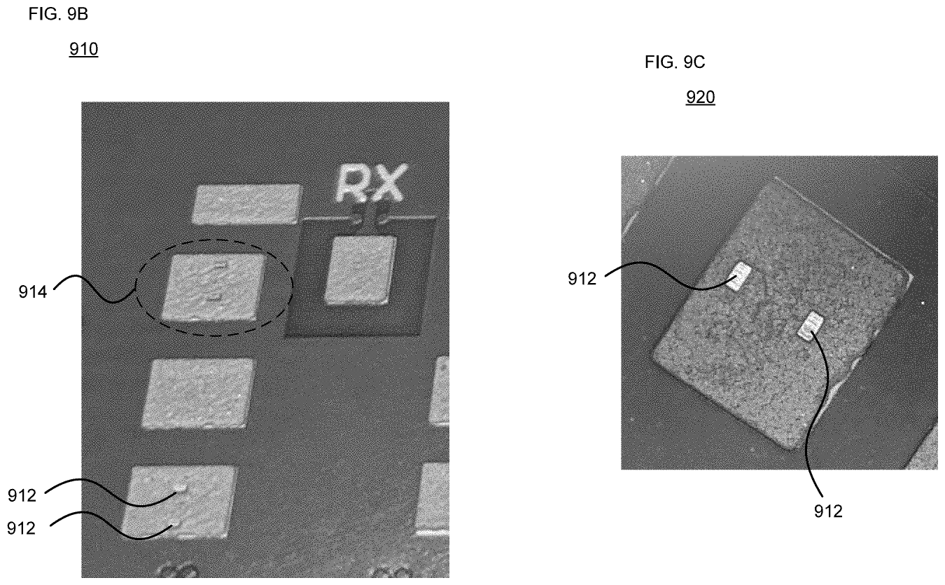

Additional solder is added to the pads prior to placement of the duplexers. For 0201 size pads (measuring 0.024×0.012 in. or 0.6×0.3 mm), each preform of additional solder may be approximately 2 kmil³ in volume, while for 0402 size pads (measuring 0.04×0.02 in. or 1.0×0.5 mm) each preform of additional solder may be approximately 15 kmil³ in volume. FIG. 9A illustrates a view 900 of a PCB having extra lines of solder 902 added to the rows of pads on which the duplexers are to be placed. FIGS. 9B-C illustrate views 910 and 920, respectively, that indicate an additional enhancement to aid in outgassing from beneath the duplexers. As shown, a pair of small solder slugs, or standoffs 912, is provided on given ones of the duplexer pads. In particular, the four corner pads 914 each contain the standoffs (solder preforms), which are illustrated in enlarged view 920 of FIG. 9C. By way of example, each standoff has an 0201 size. The placement location for the added standoffs is important to the overall process. According to one aspect, the standoffs are included on the four corner pads to hold the duplexer in place and on top of the solder preforms, making sure the part doesn't move while the PCB moves through the conveyor during reflow. The spacing between the solder preforms on a given pad is not critical, although they should be separated from each other.

In one alternative, a single standoff having an 0402 size could be used in place of the pair of 0201 standoffs. This may be done depending on the size of the components of interest (e.g., duplexers or similar devices).

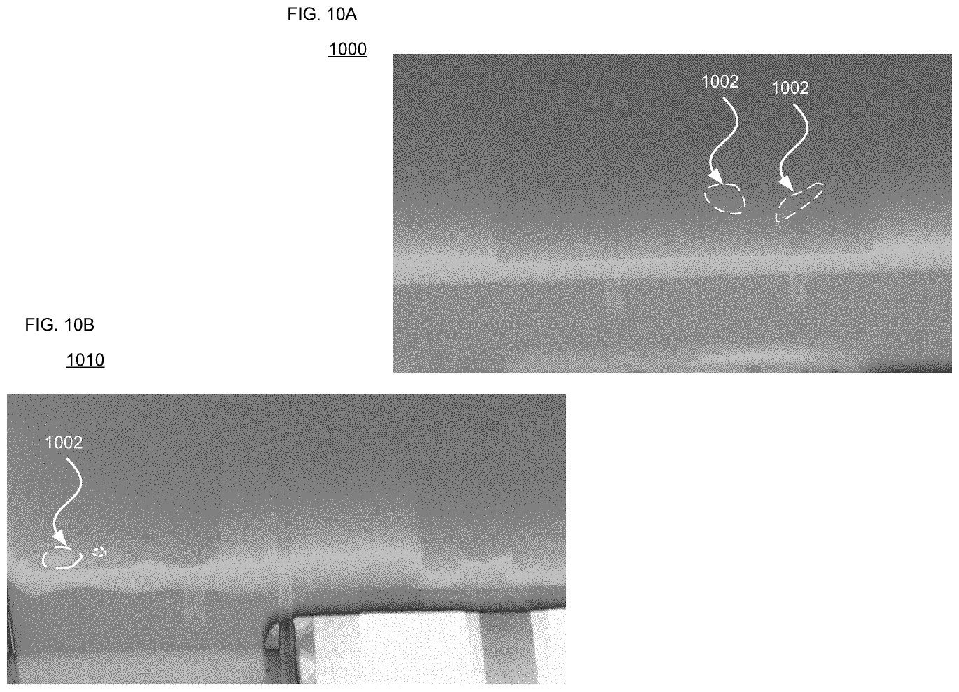

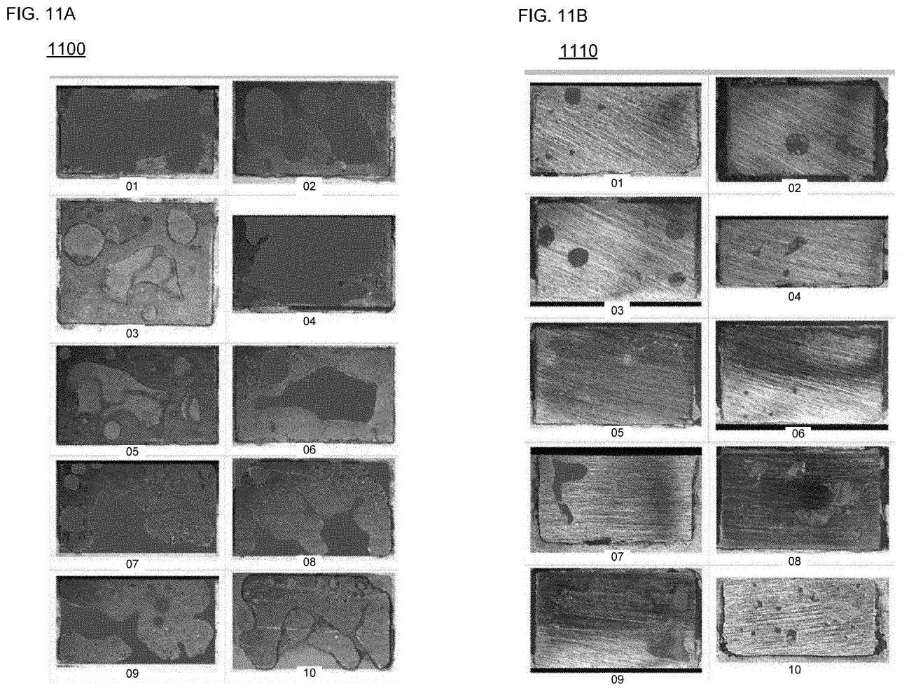

FIGS. 10A-B illustrate two example x-ray images 1000 and 1010, respectively, showing that while some voids 1002 may exceed the 10% goal for individual voids, the 25% goal for overall voids is satisfied. FIGS. 11A-B illustrate a set of 10 microsectioned pads from one PCB manufactured using a non-optimized process as seen in view 1100 of FIG. 11A, and a set of 10 microsectioned pads from another PCB manufactured an optimized process as described above, as seen in view 1110 of FIG. 11B. While microsectioning is a destructive process, it shows via the red colored areas that substantial portions of the PCB manufactured with the non-optimized process have voids which far exceed the 25% goal. In contrast, as seen in view 1110, the 25% overall void goal has been met in all instances, and the 10% individual void goal has been met in most PCBs. In particular, as shown in Table I, the average void percentage for the 10 microsectioned pads illustrated in FIG. 11A is about 45.7%, while the average void percentage for the 10 microsectioned pads illustrated in FIG. 11B is about 6.6%, which is nearly an order of magnitude smaller.

TABLE I
Void Fractions of Solder Pads

| Pad # | FIG. 11A Void % | FIG. 11B Void % |
|---|---|---|
| 01 | 83.2 | 4.8 |
| 02 | 48.6 | 8.6 |
| 03 | 38.9 | 8.4 |
| 04 | 72.9 | 3.8 |
| 05 | 38.9 | 4.1 |
| 06 | 36.4 | 0.4 |
| 07 | 37.4 | 8.1 |
| 08 | 32.5 | 11.3 |
| 09 | 34.1 | 10.5 |
| 10 | 33.6 | 6.9 |
| Average | 45.7 | 6.6 |

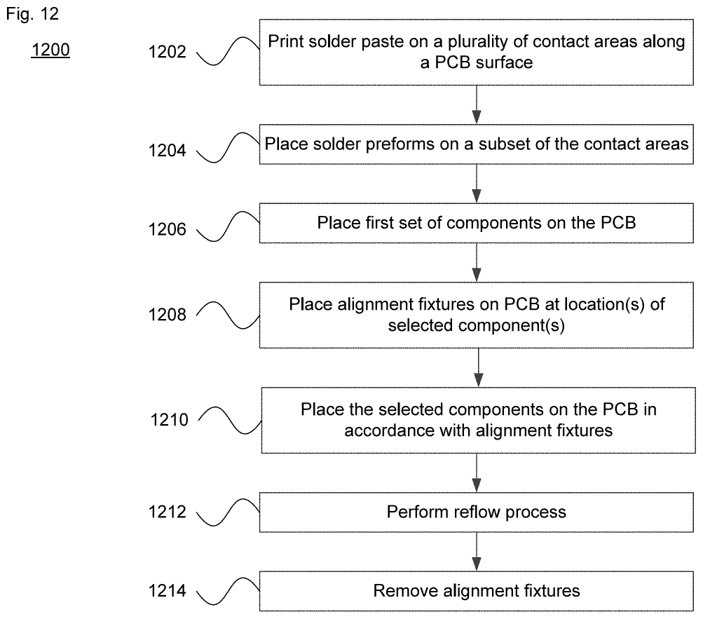

FIG. 12 illustrates a flow diagram 1200 for a method fabricating a PCB having duplexers, such as may be used in a communication module for a HAP. As shown, in block 1202, solder paste is printed on a plurality of contact areas (e.g., pads) along a PCB surface. At block 1204, a set of solder preforms are placed on a subset of the contact areas that have the solder paste. As noted above, this subset may be, e.g., along the corner pads that will be used with one or more selected components (e.g., duplexer-type devices). By way of example, each corner pad may have two preforms (standoffs) spaced apart along the pad. The amount of additional solder used for each preform can depend on the pad size (e.g., 0201 or 0402).

At block 1206, a first set of components is placed on the PCB. These components may include, e.g., inductors, capacitors, resistors, diodes, transistors and other relatively SMT devices, mechanical relays and the like. This placement may occur in conjunction with (e.g., at the same time, or just before or just after) the placement of the solder preforms, since the solder preforms are intended for use with other, selected components. At block 1208, one or more alignment fixtures are placed on the PCB. The alignment fixtures are positioned so that the one or more selected components are held in place during the reflow process. Depending on the type and/or size of the selected components, alignment fixtures may not be employed. Then, at block 1210, the one or more selected components, such as duplexers, are placed on the PCB so that the alignment fixtures maintain the positions of these components.

A reflow process is performed at block 1212 once the different components and alignment fixtures are on the PCB. The reflow process includes control of the TAL, as noted above. For instance, the ramp up rate may be no more than 1° C.-3° C./sec, and the TAL may be between 30 and 100 seconds. These factors may be impacted by the size of the PCB, the characteristics of the selected components, and other issues. Once the reflow process is finished and a determined temperature has been reached (e.g., room temperature, such as about 20° C.-22° C., or more or less), the alignment fixture(s) are removed at block 1214. At this point, the circuitry of the PCB may be tested, the solder joints may be inspected, and voids may be analyzed to determine whether they meet any predetermined criteria (e.g., IPC-A-610). By way of example, the process may result in the total size (by surface area) of all voids along the PCB not exceeding 25%, and/or any individual void not exceeding 10% of the total size.

The foregoing examples are not mutually exclusive, but may be implemented in various combinations to achieve unique advantages. As these and other variations and combinations of the features discussed above can be utilized without departing from the subject matter defined by the claims, the foregoing description of the embodiments should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible embodiments. Further, the same reference numbers in different drawings can identify the same or similar elements.

1. A method of fabricating a printed circuit board, the method comprising:
printing solder paste onto a plurality of contact areas of the printed circuit board;
placing a set of solder preforms onto a subset of the plurality of contact areas having the printed solder paste, wherein an amount of solder paste for each of the solder preforms is selected based on a pad size of each of the subset of contact areas;
placing a first set of components on the printed circuit board after printing the solder paste;
placing one or more alignment fixtures on the printed circuit board;
placing a second set of components on the printed circuit board, wherein the one or more alignment fixtures are placed so that the second set of components remains in place during fabrication of the printed circuit board;
after the one or more alignment fixtures and the second set of components are placed, performing a reflow process to heat the solder paste and the set of solder preforms to a first temperature according to a selected temperature profile; and
upon ending the reflow process and reaching a second temperature below the first temperature, removing the one or more alignment fixtures.

2. The method of claim 1, wherein the set of solder preforms placed on the subset of the plurality of contact areas are arranged so that the subset of contact areas are corner pads for the second set of components.

3. The method of claim 1, wherein each one of the solder preforms of the set comprises a pair of standoffs placed on the printed solder paste.

4. The method of claim 3, wherein the amount of solder paste for each of the solder preforms is on the order of 2 kmil³ to 15 kmil³ in volume.

5. The method of claim 1, wherein the pad size is either a 0201 size or a 0402 size.

6. The method of claim 1, wherein placing the first set of components occurs in conjunction with placing the set of solder preforms.

7. The method of claim 1, wherein performing the reflow process according to the selected temperature profile includes maintaining the first temperature for a selected time above liquideous.

8. The method of claim 7, wherein the time at above liquideous is between 30 and 100 seconds.

9. The method of claim 7, wherein achieving the first temperature includes ramping up the temperature at a selected rate.

10. The method of claim 9, wherein the selected rate is no more than 1° C.-3° C. per second.

11. The method of claim 1, further comprising performing the reflow process in the presence of nitrogen gas.

12. The method of claim 7, wherein the selected temperature profile and selected time above liquideous are chosen so that a temperature difference between the second set of components and one or more of the first set of components is maintained within a determined tolerance limit.

13. The method of claim 12, wherein the second set of components comprises a pair of duplexers, and the one or more of the first set of components comprises a mechanical relay disposed between the pair of duplexers.

14. The method of claim 1, wherein the second temperature is room temperature.

15. The method of claim 1, further comprising, after removing the one or more alignment fixtures, performing one or more of testing circuitry of the fabricated printed circuit board,
